(19) United States
(12) Patent Application Publication
(10) Pub. No.: US 2025/0331406 A1
(43) Pub. Date: Oct. 23, 2025

(54) PROTECTIVE LAYER AND DISPLAY APPARATUS INCLUDING THE PROTECTIVE LAYER

(71) Applicant: Samsung Display Co., Ltd., Yongin-si (KR)

(72) Inventor: Jonghwan Cho, Yongin-si (KR)

(21) Appl. No.: 19/046,133

(22) Filed: Feb. 5, 2025

(30) Foreign Application Priority Data
Apr. 22, 2024 (KR) 10-2024-0053544

(51) Int. Cl. H10K 59/80; H10K 102/00

(52) U.S. Cl. CPC H10K 59/8791; H10K 59/873; H10K 2102/311

(57) ABSTRACT

A protective layer includes a base layer, a first high refractive layer on the base layer and including titanium and niobium, a first low refractive layer on the first high refractive layer and including silicon and aluminum, a second high refractive layer on the first low refractive layer and including a material that is the same as that included in the first high refractive layer, a second low refractive layer on the second high refractive layer and including a material that is the same as that included in the first low refractive layer, and an anti-fingerprint layer on the second low refractive layer and including a perfluorinated compound.

### CROSS-REFERENCE TO RELATED APPLICATION

The present application claims priority to and the benefit of Korean Patent Application No. 10-2024-0053544, filed on Apr. 22, 2024, in the Korean Intellectual Property Office, the entire disclosure of which is incorporated herein by reference.

### BACKGROUND

### 1. Field

One or more embodiments relate to a protective layer and a display apparatus including the protective layer, and for example, to a protective layer in which the occurrence of cracks may be reduced during folding of a display apparatus and a display apparatus including the protective layer.

### 2. Description of the Related Art

In general, a display apparatus may be formed by coupling one or more suitable elements to each other. More specifically, a display apparatus may be formed by coupling a display panel including a display element to a cover window for protecting the display panel. Such a display apparatus may further include a protective layer to prevent or reduce the occurrence of scratches on an upper surface of the cover window, and the protective layer may include an anti-reflection layer for reducing or decreasing the reflectance of externally incident light to improve visibility of the display apparatus. Display apparatuses may be utilized as one or more suitable electronic apparatuses. For example, a display apparatus may be a mobile electronic apparatus, such as a smartphone. Such an electronic apparatus may be a foldable electronic apparatus, in which part of a display surface is folded to reduce or decrease the overall size of the electronic apparatus and/or increase the area of the display surface of the electronic apparatus.

### SUMMARY

However, such a display apparatus of the related art may have cracks occurred in the protective layer due to damage to the anti-reflection layer caused during folding of the display apparatus. This technical problem is just an example, and one or more embodiments of the presented disclosure are not limited to solving this issue alone

Aspects of one or more embodiments of the present disclosure are directed towards a protective layer in which the occurrence of cracks may be reduced during folding of a display apparatus, and a display apparatus including the protective layer.

Additional aspects will be set forth in part in the description which follows and, in part, will be apparent from the description, or may be learned by practicing one or more embodiments of the present disclosure.

One or more embodiments of the present disclosure are directed towards a protective layer including a base layer, a first high refractive layer on the base layer and including titanium and niobium, a first low refractive layer on the first high refractive layer and including silicon and aluminum, a second high refractive layer on the first low refractive layer and including a material that is the same as that included in the first high refractive layer, a second low refractive layer on the second high refractive layer and including a material that is the same as that included in the first low refractive layer, and an anti-fingerprint layer on the second low refractive layer and including a perfluorinated compound.

In one or more embodiments, the first high refractive layer may include titanium-niobium oxide.

In one or more embodiments, the first low refractive layer may include silicon-aluminum oxide.

In one or more embodiments, each of the first high refractive layer and the second high refractive layer may have a refractive index of about 1.7 to about 3.0.

In one or more embodiments, each of the first low refractive layer and the second low refractive layer may have a refractive index of about 1.3 to about 1.6.

In one or more embodiments, the first high refractive layer may include a substitutional solid solution, in which at least a portion (e.g., some) of titanium atoms of titanium oxide may be replaced by niobium atoms.

In one or more embodiments, the first low refractive layer may include a substitutional solid solution, in which at least a portion of silicon atoms of silicon oxide may be replaced by aluminum atoms.

In one or more embodiments, the first high refractive layer may include Ti₁₄Nb₃O₃₅, and the first low refractive layer may include Si₉Al₂O₁₀.

In one or more embodiments, the protective layer may further include a buffer layer between the base layer and the first high refractive layer.

In one or more embodiments, the buffer layer may include a material that is the same as that included in the first low refractive layer.

One or more embodiments of the present disclosure are directed towards a display apparatus including a display panel, a cover window on the display panel, and a protective layer on the cover window, where the protective layer includes a base layer, a first high refractive layer on the base layer and including titanium and niobium, a first low refractive layer on the first high refractive layer and including silicon and aluminum, a second high refractive layer on the first low refractive layer and including a material that is the same as that included in the first high refractive layer, a second low refractive layer on the second high refractive layer and including a material that is the same as that included in the first low refractive layer, and an anti-fingerprint layer on the second low refractive layer and including a perfluorinated compound.

In one or more embodiments, the first high refractive layer may include titanium-niobium oxide.

In one or more embodiments, the first low refractive layer may include silicon-aluminum oxide.

In one or more embodiments, each of the first high refractive layer and the second high refractive layer may have a refractive index of about 1.7 to about 3.0.

In one or more embodiments, each of the first low refractive layer and the second low refractive layer may have a refractive index of about 1.3 to about 1.6.

In one or more embodiments, the first high refractive layer may include a substitutional solid solution, in which at least a portion of titanium atoms of titanium oxide may be replaced by niobium atoms.

In one or more embodiments, the first low refractive layer may include a substitutional solid solution, in which at least a portion (e.g., some) of silicon atoms of silicon oxide may be replaced by aluminum atoms.

In one or more embodiments, the first high refractive layer may include Ti₁₄Nb₃O₃₅, and the first low refractive layer may include Si₉Al₂O₁₀.

In one or more embodiments, the display apparatus may further include a buffer layer between the base layer and the first high refractive layer. In one or more embodiments, the buffer layer may include a material that is the same as that included in the first low refractive layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to one or more embodiments;

FIG. 2 is a schematic side view of a display apparatus according to one or more embodiments;

FIG. 3 is a schematic cross-sectional view of the display apparatus of FIG. 1, taken along a line I-I′ of FIG. 1;

FIG. 4 is a schematic plan view of a display panel included in the display apparatus of FIG. 3;

FIG. 5 is an equivalent circuit diagram of a pixel circuit included in the display panel of FIG. 4;

FIG. 6 is a schematic cross-sectional view of the display panel of FIG. 4, taken along a line II-II' of FIG. 4;

FIG. 7 is a schematic cross-sectional view of a protective layer included in the display apparatus of FIG. 3; and

FIG. 8 is a schematic cross-sectional view of a protective layer included in a display apparatus according to one or more embodiments.

### DETAILED DESCRIPTION

Reference will now be made in more detail to one or more embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, one or more embodiments are merely described in more detail, by referring to the drawings, to explain aspects of the present description. As utilized herein, the term “and/or” includes any and all combinations of one or more of the associated listed items. Expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

As the present disclosure allows for one or more suitable changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

In the present disclosure, the terminology utilized herein is utilized to describe embodiments only, and is not intended to limit the present disclosure.

While such terms as “first” and “second” may be utilized to describe one or more suitable elements, such elements must not be limited to the above terms. The above terms are utilized only to distinguish one element from another.

As utilized herein, the singular forms “a,” “an,” and “the” as utilized herein are intended to include the plural forms as well unless the context clearly indicates otherwise. Further, the utilization of “may” when describing embodiments of the present disclosure refers to “one or more embodiments of the present disclosure”. It will be understood that, if (e.g., when) an element is referred to as being on another element, the element may be directly on the other element or intervening elements may be present between therebetween. In the drawings, thicknesses of some components are exaggerated for effectively explaining the technical contents. Like reference numerals refer to like elements throughout, and duplicative descriptions thereof may not be provided the specification.

It will be understood that the terms “include(s)/including,” “comprise(s)/comprising,” and “have (has)/having” as utilized herein specify the presence of stated features or elements but do not preclude the addition of one or more other features or elements.

As utilized herein, the expression “A and/or B” refers to A, B, or A and B. In addition, the expression “at least one of A and B” refers to A, B, or A and B.

It will be understood that, if (e.g., when) an element, such as a layer, a film, a region, and/or a plate, is referred to as being “on” another element, it may be directly on the other element, or intervening elements may be present therebetween.

It will be further understood that, if (e.g., when) layers, regions, and/or elements are referred to as being connected to each other, they may be directly connected to each other and/or may be indirectly connected to each other with intervening layers, regions, or elements therebetween. For example, if (e.g., when) layers, regions, and/or elements are referred to as being electrically connected to each other, they may be directly electrically connected to each other and/or may be indirectly electrically connected to each other with intervening layers, regions, and/or elements therebetween.

In contrast, when an element or layer is referred to as being “directly on,” “directly connected to”, “directly coupled to”, or “immediately adjacent to” another element or layer, there are no intervening elements or layers present.

The x-axis, the y-axis, and the z-axis are not limited to three axes of the rectangular coordinate system and may be interpreted in a broader sense. For example, the x-axis, the y-axis, and the z-axis may be normal (e.g., perpendicular) to one another or may represent different directions that are not normal (e.g., perpendicular) to one another.

One or more embodiments will be described in more detail in more detail with reference to the accompanying drawings. Those elements that may each independently be the same or are in correspondence with each other are rendered the same reference numeral regardless of the drawing number, and redundant descriptions thereof are omitted. Sizes of elements in the drawings may be exaggerated or reduced for convenience of description. For example, because sizes and thicknesses of elements in the drawings are arbitrarily illustrated for convenience of description, the following embodiments are not limited thereto.

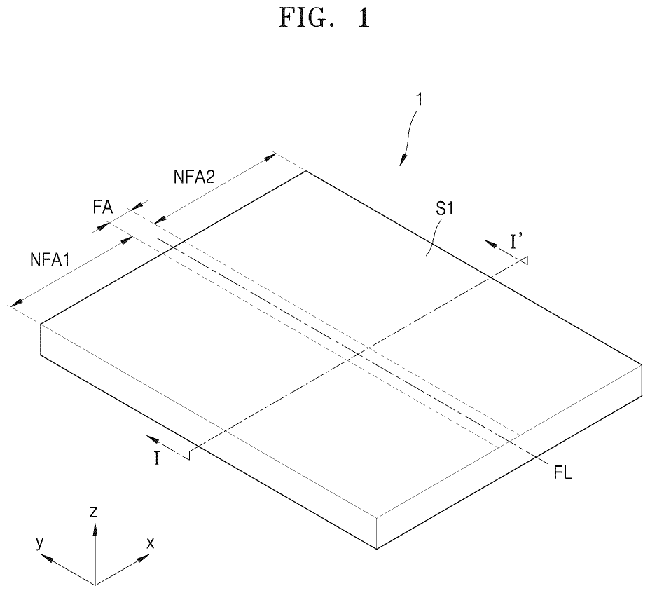

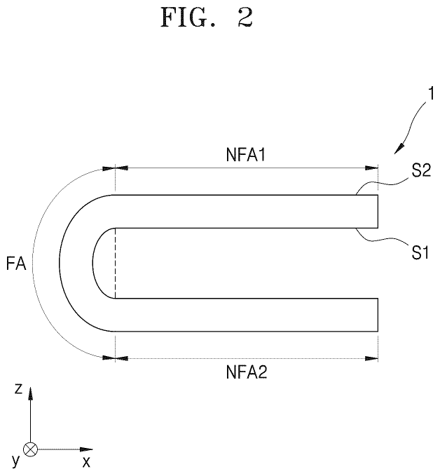

FIG. 1 is a schematic perspective view of a display apparatus 1, according to one or more embodiments. FIG. 2 is a schematic side view of the display apparatus 1, according to one or more embodiments. More specifically, FIG. 1 shows the display apparatus 1 in an unfolded state, and FIG. 2 shows the display apparatus 1 in a folded state. It may be understood that the x-axis direction may refer to a horizontal direction of the display apparatus 1, the y-axis direction may refer to a vertical direction of the display apparatus 1, and the z-axis direction may refer to a thickness direction of the display apparatus 1. For convenience of description, hereinafter, when referring to surfaces of the display apparatus 1 or each element constituting the display apparatus 1, one surface opposite to (e.g., facing) a direction (for example, a+z direction based on FIG. 1) in which the display apparatus 1 provides an image is referred to as an upper surface, and a surface that is opposite to the one surface is referred to as a lower surface. However, one or more embodiments are not limited thereto. The one surface of the display apparatus 1 or each element constituting the display apparatus 1 and the surface opposite to the one surface may be referred to as a first surface and a second surface, respectively. In one or more embodiments, the one surface of the display apparatus 1 or each element constituting the display apparatus 1 and the surface opposite to the one surface may be referred to as a third surface and a fourth surface, respectively.

Referring to FIGS. 1 and 2, the display apparatus 1 displays a moving image and/or a still image. The display apparatus 1 may refer to any electronic device that provides a display screen. For example, a television, a notebook computer, a monitor, a billboard, the Internet of things, a mobile phone, a smartphone, a tablet personal computer (PC), a digital watch, a smartwatch, a watch phone, a head-mounted display, a mobile communication terminal, an electronic notebook, an e-book, a portable multimedia player (PMP), a navigation device, a game console, a digital camera, and/or a camcorder, which provides a display screen, may be included in the display apparatus 1.

The display apparatus 1 may have a polygonal shape including a quadrangular shape. For example, the display apparatus 1 may have a rectangular shape having a horizontal length that is less than a vertical length, a rectangular shape having a horizontal length that is greater than a vertical length, and/or a square shape. In one or more embodiments, the display apparatus 1 may have one or more suitable shapes, such as an oval shape and/or a circular shape. Although FIG. 1 shows the display apparatus 1 having a rectangular shape, in which a horizontal length is less than a vertical length, one or more embodiments are not limited thereto.

The display apparatus 1 may include a first surface S1 and a second surface S2 that is opposite to the first surface S1. In one or more embodiments, the first surface S1 may be an upper surface (in the +z direction) of the display apparatus 1. The second surface S2 may be a lower surface (in a −z direction) of the display apparatus 1. The display apparatus 1 may display an image on the first surface S1. For example, the first surface S1 may include a display surface. In one or more embodiments, the display apparatus 1 may also display an image on the second surface S2.

The display apparatus 1 may be folded. For example, at least a portion of the display apparatus 1 may have flexibility, and the display apparatus 1 may be folded as the portion having flexibility is bent. Accordingly, the display apparatus 1 may include a folded area and a non-folded area that is arranged on at least a side of the folded area and is not folded. The expression “non-folded” utilized herein may refer to that a portion is not folded, and may cover not only a case where a portion is hard with no flexibility and thus is not capable of being folded, but also a case where a portion has flexibility but is not folded. The display apparatus 1 may display an image not only in the non-folded area but also in the folded area.

As shown in FIG. 1, the display apparatus 1 may include a first non-folding area NFA1, a second non-folding area NFA2, and a foldable area FA. The first non-folding area NFA1 and the second non-folding area NFA2 may be non-folded areas, and the foldable area FA may have flexibility and may be a foldable area.

The foldable area FA may be extended in a direction crossing a virtual straight line that connects the first non-folding area NFA1 to the second non-folding area NFA2. More specifically, if (e.g., when) the display apparatus 1 is unfolded, the first non-folding area NFA1 and the second non-folding area NFA2 may be apart from each other in a first direction (e.g., the x-axis direction). The foldable area FA may be between (e.g., arranged between) the first non-folding area NFA1 and the second non-folding area NFA2. More specifically, the first non-folding area NFA1 may be adjacent to one side of the foldable area FA, and the second non-folding area NFA2 may be adjacent to the other side of the foldable area FA. If (e.g., when) the display apparatus 1 is unfolded, the foldable area FA may be extended in a second direction (e.g., the y-axis direction) crossing the first direction.

A folding line FL may be provided in the foldable area FA in the second direction (e.g., the y-axis direction), in which the foldable area FA is extended. Accordingly, the display apparatus 1 may be folded in the foldable area FA. The foldable area FA and the folding line FL of the foldable area FA may overlap at least a portion of the display apparatus 1 where an image is displayed, and if (e.g., when) the display apparatus 1 is folded, the portion where an image is displayed may be folded.

Although the first non-folding area NFA1 and the second non-folding area NFA2 have the same area or similar areas and the display apparatus 1 includes one foldable area FA in FIG. 1 for convenience of description, one or more embodiments are not limited thereto. For example, the first non-folding area NFA1 and the second non-folding area NFA2 may have different areas from each other. In addition, the display apparatus 1 may include a plurality of foldable areas FA. In this case, a plurality of non-folding areas may be apart from each other, and each of the plurality of foldable areas FA may be between the non-folding areas. Each foldable area FA may be folded along the folding line FL, and a plurality of folding lines FL may be provided.

Although the folding line FL passes through the center of the foldable area FA and the foldable area FA is line-symmetric with respect to the folding line FL in FIG. 1, one or more embodiments are not limited thereto. For example, the folding line FL may be asymmetrically provided in the foldable area FA.

As shown in FIG. 2, the display apparatus 1 may be folded along the folding line FL, such that the first surface S1 of the first non-folding area NFA1 and the first surface S1 of the second non-folding area NFA2 may oppose (e.g., face) each other. For example, as the foldable area FA of the display apparatus 1 is bent, the first surface S1 of the first non-folding area NFA1 and the first surface S1 of the second non-folding area NFA2 may be located to oppose (e.g., face) each other. That is, the first surface S1 of NFA1 faces the first surface S1 of NFA2 and is opposite to (or is facing away from) a second S2. Here, even if (e.g., when) the display apparatus 1 is folded, the foldable area FA may be extended in a direction crossing a virtual straight line that connects the first non-folding area NFA1 to the second non-folding area NFA2. More specifically, if (e.g., when) the display apparatus 1 is folded, the foldable area FA may be extended in the second direction (e.g., the y-axis direction) crossing a virtual straight line (e.g., a straight line parallel to the z-axis direction) that connects the first non-folding area NFA1 to the second non-folding area NFA2.

The foldable area FA may be bent and then may be unfolded again. For example, the display apparatus 1 may be a foldable display apparatus. The expression “folded” utilized herein refers to that a portion is not fixed in shape but is transformed from an original shape to another shape, and may be folded, curved or bent along at least one specific line, such as the folding line FL. Accordingly, although FIG. 2 shows that the display apparatus 1 is folded, such that the first surface S1 of the first non-folding area NFA1 and the first surface S1 of the second non-folding area NFA2 are parallel to each other and oppose each other (e.g., face each other in up and down opposite directions), this is just one embodiment and is not limiting. For example, the display apparatus 1 may be folded, such that the first surface S1 of the first non-folding area NFA1 and the first surface S1 of the second non-folding area NFA2 may form a certain angle (e.g., an acute angle, a right angle, and/or an obtuse angle) with the foldable area FA therebetween.

In addition, although FIG. 2 shows that the display apparatus 1 is folded, for example, in-folded, such that a portion of the first surface S1 and another portion of the first surface S1 may oppose (e.g., face) each other, one or more embodiments are not limited thereto. For example, the display apparatus 1 may be folded, for example, out-folded, such that a portion of the second surface S2 and another portion of the second surface S2 may oppose (e.g., face) each other. For example, the display apparatus 1 may be of an in-folding type or kind, in which portions of a display surface may oppose (e.g., face) each other if (e.g., when) the display apparatus 1 is folded, and/or an out-folding type or kind, in which a display surface is exposed to the outside if (e.g., when) the display apparatus 1 is folded. Hereinafter, a case where the display apparatus 1 is of an in-folding type or kind will be mainly described for convenience.

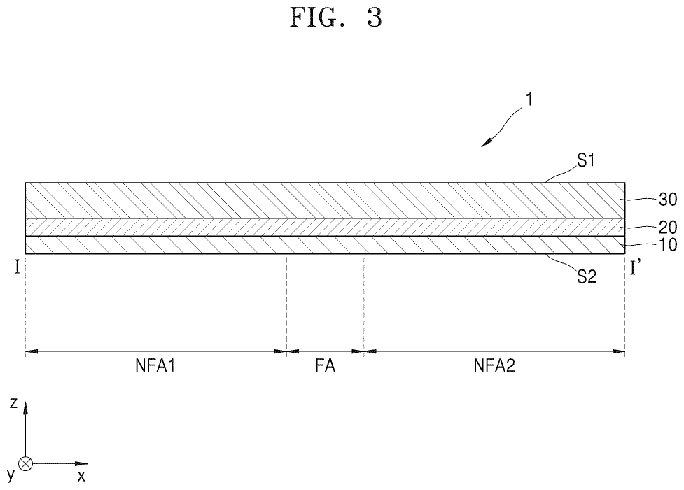

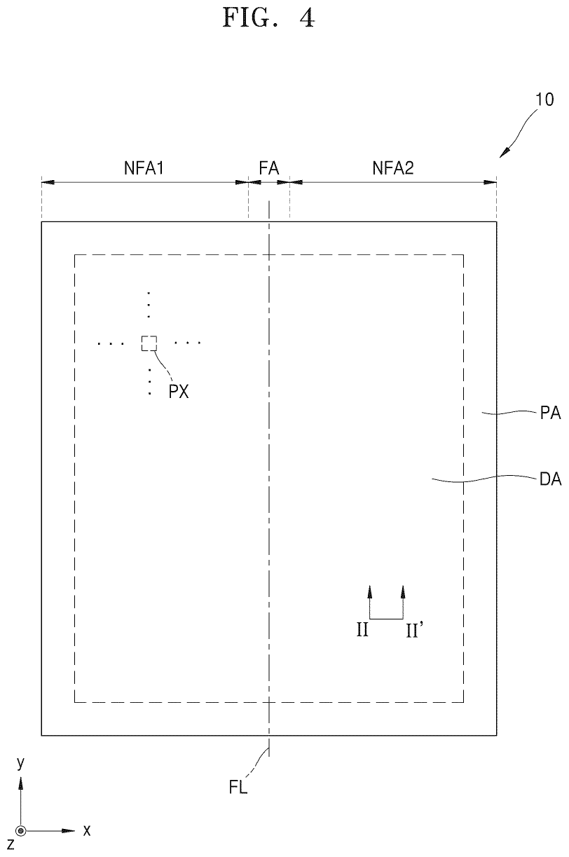

FIG. 3 is a schematic cross-sectional view of the display apparatus 1 of FIG. 1, taken along a line I-I′ of FIG. 1. FIG. 4 is a schematic plan view of a display panel 10 included in the display apparatus 1 of FIG. 3. As shown in FIG. 3, the display apparatus 1 may include the display panel 10, a cover window 20, and a protective layer 30. In some embodiments, the display apparatus 1 may further include one or more suitable elements in addition to the elements shown in FIG. 3.

The display panel 10 may display an image. For example, an image provided by the display apparatus 1 may be understood as being implemented by the display panel 10. To this end, the display panel 10 may include a plurality of display elements, and the plurality of display elements may be to emit red, green, and/or blue light. Accordingly, the display panel 10 may display an image through light emitted from the plurality of display elements.

In one or more embodiments, the display element may be an organic light-emitting diode including an organic emission layer. In one or more embodiments, the display element may be a light-emitting diode (LED). The LED may have a micro-scale or nano-scale size. For example, the LED may be a micro LED. In one or more embodiments, the LED may be a nanorod LED. The nanorod LED may include gallium nitride (GaN). In one or more embodiments, a color conversion layer may be on (e.g., arranged on the nanorod LED. The color conversion layer may include quantum dots. In one or more embodiments, the display element may be a quantum dot LED including a quantum dot emission layer. In one or more embodiments, the display element may be an inorganic light-emitting diode including an inorganic semiconductor. Elements included in the display panel 10 will be described in more detail.

As described above, the display apparatus 1 may include the first non-folding area NFA1, the second non-folding area NFA2, and the foldable area FA. Because the display apparatus 1 includes the display panel 10, the display panel 10 may include the first non-folding area NFA1, the second non-folding area NFA2, and the foldable area FA as described above. For convenience, the following will be described assuming that the display panel 10 includes the first non-folding area NFA1, the second non-folding area NFA2, and the foldable area FA.

For example, if (e.g., when) the display panel 10 is unfolded, the first non-folding area NFA1 and the second non-folding area NFA2 may be apart from (e.g., space from or separated from) each other in a first direction (e.g., the x-axis direction). The foldable area FA may be between (e.g., arranged between) the first non-folding area NFA1 and the second non-folding area NFA2 and may be extended in a direction crossing a virtual straight line that connects the first non-folding area NFA1 to the second non-folding area NFA2. The folding line FL may be provided in the foldable area FA in a second direction (e.g., the y-axis direction), in which the foldable area FA is extended. Accordingly, the display panel 10 may be folded in the foldable area FA.

As shown in FIG. 4, the display panel 10 may include a display area DA, in which a plurality of pixels PX are arranged and a peripheral area PA located outside the display area DA.

Each pixel PX of the display panel 10 is an area capable of emitting light of a certain color, and the display panel 10 may provide an image by using light emitted from the pixels PX. For example, each pixel PX may be to emit red, green, and/or blue light. For example, one display element may correspond to one pixel.

The display area DA is an area that provides an image, and as shown in FIG. 4, may have a polygonal shape including a quadrangular shape. For example, the display area DA may have a rectangular shape having a horizontal length that is greater than a vertical length, a rectangular shape having a horizontal length that is less than a vertical length, and/or a square shape. In one or more embodiments, the display area DA may have one or more suitable shapes, such as an oval shape and/or a circular shape.

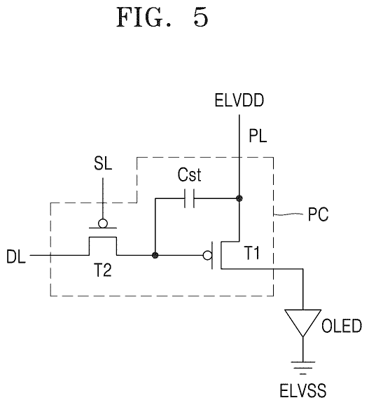

The peripheral area PA is a non-display area where no image is provided, and may entirely be around (e.g., surround) the display area DA. More specifically, pixels PX are not arranged in the peripheral area PA, and a driver for providing an electrical signal or power to the pixels PX may be arranged in the peripheral area PA. Pads may be arranged in the peripheral area PA, and an electronic device or a printed circuit board may be electrically connected to the pads. Each pad may be apart from (e.g., spaced from or separated from) another in the peripheral area PA, and each pad may be electrically connected to a plurality of connection wires in the peripheral area PA. The connection wires may be electrically connected with signal lines in the display area DA, for example, data lines DL (refer to FIG. 5) (or scan lines SL (refer to FIG. 5)) to the pads.

The cover window 20 may be on (e.g., arranged on) the display panel 10. More specifically, the cover window 20 may be arranged on an upper surface of the display panel 10. In one or more embodiments, the cover window 20 may cover an upper surface of the display panel 10. An image displayed by the display panel 10 may be provided to a user through the cover window 20 having transparency.

The cover window 20 may protect an upper surface of the display panel 10. The cover window 20 may have significant strength and hardness to protect the display panel 10 from external impact. In addition, the cover window 20 may have a high transmittance to transmit light emitted from the display panel 10 and may be thin enough to reduce the weight of the display apparatus 1. Because the cover window 20 forms the exterior of the display apparatus 1, the cover window 20 may include flat and/or curved surfaces corresponding to a shape of the display apparatus 1.

The cover window 20 may be a flexible window. The cover window 20 may protect the display panel 10 by being easily bent according to an external force without causing cracks and/or the like. The cover window 20 may include glass or plastic. In one or more embodiments, the cover window 20 may include ultra thin glass (UTG™) of which strength is increased by a method such as chemical strengthening and/or thermal strengthening. In one or more embodiments, the cover window 20 may include polymer resin.

In one or more embodiment, an adhesive member may be between (e.g., arranged between) the display panel 10 and the cover window 20. The adhesive member may include at least one of optical clear resin (OCR), optical clear adhesive (OCA), and/or pressure-sensitive adhesive (PSA). The adhesive member may couple the display panel 10 and the cover window 20 to each other.

The protective layer 30 may be on (e.g., arranged on) the cover window 20. The protective layer 30 may protect the cover window 20 and may prevent, reduce, or decrease the occurrence of scratches on an upper surface of the cover window 20. The protective layer 30 may include a plurality of sub-layers. In one or more embodiments, the protective layer 30 may include an organic layer. For example, the protective layer 30 may include an acryl-based polymer. If (e.g., when) the protective layer 30 includes an organic layer, the protective layer 30 may have improved flexibility. In one or more embodiments, the protective layer 30 may further include an inorganic layer. A structure of the protective layer 30 and a material included in the protective layer 30 will be described in more detail.

An adhesive member may be between (e.g., arranged between) the cover window 20 and the protective layer 30. The adhesive member may include at least one of OCR, OCA, and/or PSA. The adhesive member may couple the cover window 20 and the protective layer 30 to each other.

FIG. 5 is an equivalent circuit diagram of a pixel circuit PC included in the display panel 10 of FIG. 4. The pixel circuit PC may be electrically connected to a display element, and one display element may correspond to one pixel. FIG. 5 shows an organic light-emitting diode OLED as the display element. In one or more embodiments, the display element may be to emit red, green, or blue light.

The pixel circuit PC may include a first transistor T1, a second transistor T2, and/or a storage capacitor Cst. The second transistor T2, which is a switching transistor, may be connected to a scan line SL and a data line DL, and may be turned on by a switching signal input from the scan line SL to transmit a data signal input from the data line DL to the first transistor T1. The storage capacitor Cst may have one end electrically connected to the second transistor T2 and the other end electrically connected to a driving voltage line PL, and may store a voltage corresponding to the difference between a voltage received from the second transistor T2 and a driving power voltage ELVDD supplied to the driving voltage line PL.

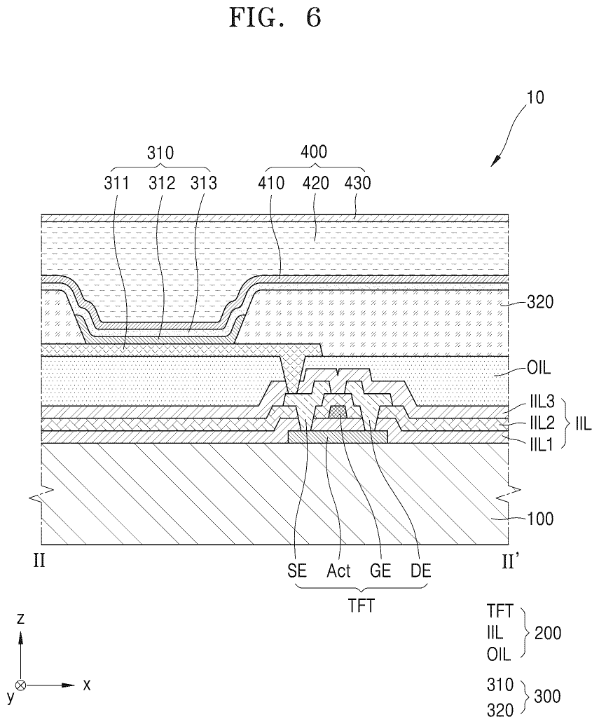

The first transistor T1, which is a driving transistor, may be connected to the driving voltage line PL and the storage capacitor Cst, and may be to control the volume of a driving current flowing from the driving voltage line PL to the organic light-emitting diode OLED, in response to a voltage value stored in the storage capacitor Cst. The organic light-emitting diode OLED may be to emit light having a certain luminance according to the driving current. An opposite electrode 313 (refer to FIG. 6) of the organic light-emitting diode OLED may receive an electrode power voltage ELVSS.

Although FIG. 5 illustrates the pixel circuit PC including two transistors and one storage capacitor, one or more embodiments are not limited thereto. For example, the number of transistors or the number of storage capacitors may be variously modified according to the design of the pixel circuit PC.

FIG. 6 is a schematic cross-sectional view of the display panel 10 of FIG. 4, taken along a line II-II' of FIG. 4. As shown in FIG. 6, the display panel 10 may include a substrate 100, a pixel circuit layer 200, a display element layer 300, and/or an encapsulation layer 400.

The substrate 100 may include glass, metal, and/or polymer resin. The substrate 100 may be flexible or bendable. In this case, the substrate 100 may include, for example, polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate 100 may be variously modified, for example, to have a multi-layer structure including two layers and a barrier layer between the two layers, the two layers including the above polymer resin and the barrier layer including an inorganic material (e.g., silicon oxide (SiO_{X}), silicon nitride (SiN_{X}), silicon oxynitride (SiO_{X}N_{Y}), and/or the like).

The pixel circuit layer 200 may be on (e.g., arranged on) the substrate 100. The pixel circuit layer 200 may include a thin-film transistor TFT, an inorganic insulating layer IIL, and/or an organic insulating layer OIL. The thin-film transistor TFT may include a semiconductor layer Act, a gate electrode GE, a source electrode SE, and/or a drain electrode DE. The inorganic insulating layer IIL may include a gate insulating layer IIL1, a first interlayer insulating layer IIL2, and/or a second interlayer insulating layer IIL3. For convenience of illustration, one thin-film transistor TFT is shown in FIG. 6, and the thin-film transistor TFT may correspond to the first transistor T1 (refer to

FIG. 5) described above.

The semiconductor layer Act may be on (e.g., arranged on) the substrate 100. The semiconductor layer Act may include polysilicon. In one or more embodiments, the semiconductor layer Act may also or alternatively include amorphous silicon, an oxide semiconductor, and/or an organic semiconductor. In one or more embodiments, the semiconductor layer Act may include a channel region and a source region, and a drain region respectively may be arranged on both sides (e.g., opposite sides) of the channel region.

The gate insulating layer IIL1 may be on (e.g., arranged on) the semiconductor layer Act and the substrate 100. The gate insulating layer IIL1 may include an inorganic insulating material, such as silicon oxide (SiO_{X}), silicon nitride (SiN_{X}), silicon oxynitride (SiO_{X}N_{Y}), aluminum oxide (Al_{X}O_{Y}, e.g., Al₂O₃), titanium oxide (TiOX, e.g., TiO₂), tantalum oxide (Ta_{X}O_{Y}, e.g., Ta₂O₅), hafnium oxide (HfO_{X}, e.g., HfO₂), and/or zinc oxide (ZnOₓ). The zinc oxide (ZnO_{X}) may include zinc oxide (ZnO) and/or zinc peroxide (ZnO₂).

The gate electrode GE may be on (e.g., arranged on) the gate insulating layer IIL1. For example, the gate insulating layer IIL1 may be arranged between the semiconductor layer Act and the gate electrode GE to provide insulation between the semiconductor layer Act and the gate electrode GE. The gate electrode GE may overlap the channel region of the semiconductor layer Act. The gate electrode GE may include a low-resistance metal material. In one or more embodiments, the gate electrode GE may include a conductive material including molybdenum (Mo), aluminum (Al), copper (Cu), titanium (Ti), and/or the like, and may have a single-layer or multi-layer structure including the above conductive material.

The first interlayer insulating layer IIL2 may be on (e.g., arranged on) the gate electrode GE and the gate insulating layer IIL1. The first interlayer insulating layer IIL2 may include an inorganic insulating material, such as silicon oxide (SiO_{X}), silicon nitride (SiN_{X}), silicon oxynitride (SiO_{X}N_{Y}), aluminum oxide (Al_{X}O_{Y}, e.g., Al₂O₃), titanium oxide (TiOₓ, e.g., TiO₂), tantalum oxide (Ta_{X}O_{Y}, e.g., Ta₂O₅), hafnium oxide (HfOₓ, e.g., HfO₂), and/or zinc oxide (ZnOₓ).

The source electrode SE and the drain electrode DE may be arranged on the first interlayer insulating layer IIL2. Each of the source electrode SE and the drain electrode DE may be connected to the semiconductor layer Act through a contact hole in the gate insulating layer IIL1 and the first interlayer insulating layer IIL2. At least one of the source electrode SE or the drain electrode DE may include a conductive material including molybdenum (Mo), aluminum (Al), copper (Cu), and/or titanium (Ti), and may have a single-layer or multi-layer structure including the above conductive material. In one or more embodiments, at least one of the source electrode SE or the drain electrode DE may have a multi-layer structure of Ti/Al/Ti (e.g., a multi-layer structure including a Ti layer, an Al layer, and another Ti layer).

The second interlayer insulating layer IIL3 may be on (e.g., arranged on) the source electrode SE, the drain electrode DE, and/or the first interlayer insulating layer IIL2. The second interlayer insulating layer IIL3 may include an inorganic insulating material, such as silicon oxide (SiO_{X}), silicon nitride (SiN_{X}), silicon oxynitride (SiO_{X}N_{Y}), aluminum oxide (Al_{X}O_{Y}, e.g., Al₂O₃), titanium oxide (TiOₓ, e.g., TiO₂), tantalum oxide (Ta_{X}O_{Y}, e.g., Ta₂O₅), hafnium oxide (HfO_{X}, e.g., HfO₂), and/or zinc oxide (ZnOₓ).

The organic insulating layer OIL may be on (e.g., arranged on) the second interlayer insulating layer IIL3. The organic insulating layer OIL may substantially planarize (e.g., flatten) the top of the pixel circuit layer 200. The organic insulating layer OIL may include, for example, an organic material, such as acryl, benzocyclobutene (BCB), and/or hexamethyldisiloxane (HMDSO). Although FIG. 6 shows the organic insulating layer OIL as a single layer, the organic insulating layer OIL may have one or more suitable modifications, such as a multi-layer structure.

The display element layer 300 may be on (e.g., arranged on) the pixel circuit layer 200. The display element layer 300 may include a display element 310 and a pixel-defining layer 320. The display element 310 may be electrically connected to the thin-film transistor TFT. The display element 310 may be, for example, an organic light-emitting diode having a pixel electrode 311, an opposite electrode 313, and an intermediate layer 312 therebetween and including an emission layer. If (e.g., when) the display element 310 is referred to as being electrically connected to the thin-film transistor TFT, it may be construed as meaning that the pixel electrode 311 of the organic light-emitting diode is electrically connected to the thin-film transistor TFT.

The pixel electrode 311 may be in contact with one of the source electrode SE and/or the drain electrode DE through a contact hole in the second interlayer insulating layer IIL3 and the organic insulating layer OIL, and thus may be electrically connected to the thin-film transistor TFT. The pixel electrode 311 may include conductive oxide, such as indium tin oxide (In_{X}T_{Y}O_{Z}, e.g., ITO), indium zinc oxide (In_{X}Zn_{Y}O_{Z}, e.g., IZO), zinc oxide (ZnOₓ, e.g., ZnO), indium oxide (In_{X}O_{Y}, e.g., In₂O₃), indium gallium oxide (In_{X}Ga_{Y}O_{Z}, e.g., IGO), and/or aluminum zinc oxide (Al_{X}Zn_{Y}O_{Z}, e.g., AZO). In one or more embodiments, the pixel electrode 311 may include a reflection layer including silver (Ag), magnesium (Mg), aluminum (Al), platinum (Pt), palladium (Pd), gold (Au), nickel (Ni), neodymium (Nd), iridium (Ir), chromium (Cr), and/or a compound thereof. In one or more embodiments, the pixel electrode 311 may further include a layer formed of ITO, IZO, ZnO, and/or In₂O₃ on/under (e.g., on and/or under) the above-described reflection layer.

The pixel-defining layer 320 may cover edges of the pixel electrode 311. The pixel-defining layer 320 may include a pixel opening, and the pixel opening may overlap the pixel electrode 311. The pixel opening may define an emission area of light emitted from the display element 310. The pixel-defining layer 320 may include an organic insulating material and/or an inorganic insulating material. In one or more embodiments, the pixel-defining layer 320 may include a light-blocking material.

The intermediate layer 312 may be on (e.g., arranged on) the pixel electrode 311 and the pixel-defining layer 320. The intermediate layer 312 may include a low-molecular weight material and/or a polymer material. If (e.g., when) the intermediate layer 312 includes a low-molecular weight material, the intermediate layer 312 may have a structure, in which a hole injection layer (HIL), a hole transport layer (HTL), an emission layer (EML), an electron transport layer (ETL), and an electron injection layer (EIL) are stacked in a single or complex structure, and may be formed by vacuum deposition. If (e.g., when) the intermediate layer 312 includes a polymer material, the intermediate layer 312 may have a structure including an HTL and an EML. In some embodiments, the HTL may include poly(3,4-ethylenedioxythiophene) (PEDOT), and the EML may include a polymer material, such as a polyphenylene vinylene (PPV)-based material, a polyfluorene-based material, and/or the like. The intermediate layer 312 may be formed by screen printing, inkjet printing, laser induced thermal imaging (LITI), and/or the like. However, the intermediate layer 312 is not limited thereto and may have any of one or more suitable other structures. In addition, the intermediate layer 312 may include a single layer over a plurality of pixel electrodes 311, or may include patterned layers respectively corresponding to the plurality of pixel electrodes 311.

The opposite electrode 313 may be on (e.g., arranged on) the intermediate layer 312 and the pixel-defining layer 320. The opposite electrode 313 may be formed as a single electrode for a plurality of organic light-emitting diodes to correspond to the plurality of pixel electrodes 311. The opposite electrode 313 may include a light-transmissive conductive layer formed of ITO, In₂O₃, and/or IZO and may include a semi-transmissive layer including metal, such as Al and/or Ag. For example, the opposite electrode 313 may be a semi-transmissive layer including Mg and/or Ag.

Because the display element 310 may be easily damaged by external moisture and/or oxygen, the encapsulation layer 400 may cover and protect the display element 310. As shown in FIG. 6, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and may include silicon oxide (SiO_{X}), silicon nitride (SiN_{X}) and/or silicon oxynitride (SiO_{X}N_{Y}). In some embodiments, other layers such as a capping layer may be between (e.g., arranged between) the first inorganic encapsulation layer 410 and the opposite electrode 313. Because the first inorganic encapsulation layer 410 is formed along a lower structure, an upper surface of the first inorganic encapsulation layer 410 may not be flat as shown in FIG. 6. The organic encapsulation layer 420 may cover the first inorganic encapsulation layer 410, and unlike the first inorganic encapsulation layer 410, the organic encapsulation layer 420 may have a substantially flat upper surface. The organic encapsulation layer 420 may include at least one material selected from among the group consisting of polyethylene terephthalate, polyethylene naphthalate, polycarbonate, polyimide, polyethylene sulfonate, polyoxymethylene, polyarylate, and/or HMDSO. The second inorganic encapsulation layer 430 may cover the organic encapsulation layer 420 and may include silicon oxide (SiO_{X}), silicon nitride (SiN_{X}) and/or silicon oxynitride (SiO_{X}N_{Y}).

As described above, the encapsulation layer 400 may include the first inorganic encapsulation layer 410, the organic encapsulation layer 420, and the second inorganic encapsulation layer 430, and accordingly, even if (e.g., when) cracks occur in the encapsulation layer 400, such a multi-layer structure may prevent or reduce the cracks from being connected between the first inorganic encapsulation layer 410 and the organic encapsulation layer 420 and/or between the organic encapsulation layer 420 and the second inorganic encapsulation layer 430. Thus, a formation of a path through which external moisture or oxygen penetrates the display panel 10 may be prevented or reduced.

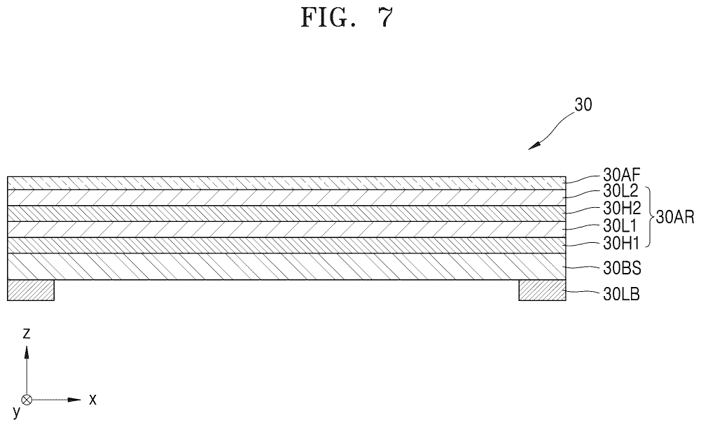

FIG. 7 is a schematic cross-sectional view of the protective layer 30 included in the display apparatus 1 of FIG. 3. As shown in FIG. 7, the protective layer 30 may include a base layer 30BS, an anti-reflection layer 30AR, an anti-fingerprint layer 30AF, and a light-blocking layer 30LB.

The base layer 30BS may be on (e.g., arranged on) the cover window 20. The base layer 30BS may be a plastic film including polymer resin. For example, the base layer 30BS may include at least one of polymer resins, such as polyethylene terephthalate (PET), poly(butylene terephthalate) (PBT), polycarbonate (PC), polyethylene naphthalate (PEN), polystyrene (PS), polymethyl methacrylate (PMMA), polyvinylchloride (PVC), polyethersulfone (PES), polypropylene (PP), and/or polyamide (PA).

The anti-reflection layer 30AR may be on (e.g., arranged on) the base layer 30BS. The anti-reflection layer 30AR may reduce or decrease the reflectance of externally incident light. The anti-reflection layer 30AR may have a stacked structure including a plurality of sub-layers. More specifically, the anti-reflection layer 30AR may include a first high refractive layer 30H1, a first low refractive layer 30L1, a second high refractive layer 30H2, and/or a second low refractive layer 30L2.

The first high refractive layer 30H1 may be on (e.g., arranged on) the baser layer 30BS. The first high refractive layer 30H1 may include a high-refractive material. The first high refractive layer 30H1 may include oxide, and the first high refractive layer 30H1 may include titanium (Ti) and niobium (Nb). In one or more embodiments, the first high refractive layer 30H1 may include titanium-niobium oxide. For example, the titanium-niobium oxide may be Ti₁₄Nb₃O₃₅, and the titanium-niobium oxide may be provided as a substitutional solid solution. For example, the titanium-niobium oxide may be provided as a substitutional solid solution, in which at least a portion of titanium atoms of titanium oxide may be replaced by niobium atoms. For example, the first high refractive layer 30H1 may include a substitutional solid solution, in which at least a portion of titanium atoms of titanium oxide may be replaced by niobium atoms.

In one or more embodiments, a refractive index of the first high refractive layer 30H1 may be about 1.7 to about 3.0. More specifically, a refractive index of the first high refractive layer 30H1 with respect to a wavelength of 550 nanometers (nm) may be about 2.17.

The first low refractive layer 30L1 may be on (e.g., arranged on) the first high refractive layer 30H1. The first low refractive layer 30L1 may include a low-refractive material. The first low refractive layer 30L1 may include oxide, and the first low refractive layer 30L1 may include silicon (Si) and aluminum (Al). In one or more embodiments, the first low refractive layer 30L1 may include silicon-aluminum oxide. For example, the silicon-aluminum oxide may be Si₉Al₂O₁₀, and the silicon-aluminum oxide may be provided as a substitutional solid solution. For example, the silicon-aluminum oxide may be provided as a substitutional solid solution, in which at least a portion of silicon atoms of silicon oxide may be replaced by aluminum atoms. For example, the first low refractive layer 30L1 may include a substitutional solid solution, in which at least a portion of silicon atoms of silicon oxide may be replaced by aluminum atoms.

In one or more embodiments, a refractive index of the first low refractive layer 30L1 may be less than a refractive index of the first high refractive layer 30H1. A refractive index of the first low refractive layer 30L1 may be about 1.4 to about 1.6. More specifically, a refractive index of the first low refractive layer 30L1 with respect to a wavelength of 550 nm may be about 1.48.

The second high refractive layer 30H2 may be on (e.g., arranged on) the first low refractive layer 30L1. The second high refractive layer 30H2 may include a high-refractive material. The second high refractive layer 30H2 may include a material that is the same as that included in the first high refractive layer 30H1. For example, the second high refractive layer 30H2 may be composed of the same material as the first high refractive layer 30H1. More specifically, the second high refractive layer 30H2 may include oxide, and the second high refractive layer 30H2 may include titanium (Ti) and niobium (Nb). In one or more embodiments, the second high refractive layer 30H2 may include titanium-niobium oxide. For example, the titanium-niobium oxide may be Ti₁₄Nb₃O₃₅, and the titanium-niobium oxide may be provided as a substitutional solid solution. For example, the titanium-niobium oxide may be provided as a substitutional solid solution, in which at least a portion of titanium atoms of titanium oxide may be replaced by niobium atoms. For example, the second high refractive layer 30H2 may include a substitutional solid solution, in which at least a portion of titanium atoms of titanium oxide may be replaced by niobium atoms.

In one or more embodiments, a refractive index of the second high refractive layer 30H2 may be the same as or similar to a refractive index of the first high refractive layer 30H1. The refractive index of the second high refractive layer 30H2 may be about 1.7 to about 3.0. More specifically, a refractive index of the second high refractive layer 30H2 with respect to a wavelength of 550 nm may be about 2.17. For example, each of the first high refractive layer 30H1 and the second high refractive layer 30H2 may have a refractive index of about 1.7 to about 3.0.

The second low refractive layer 30L2 may be on (e.g., arranged on) the second high refractive layer 30H2. The second low refractive layer 30L2 may include a low-refractive material. The second low refractive layer 30L2 may include a material that is the same as that included in the first low refractive layer 30L1. For example, the second low refractive layer 30L2 may be composed of the same material as the first low refractive layer 30L1. More specifically, the second low refractive layer 30L2 may include oxide, and the second low refractive layer 30L2 may include silicon (Si) and aluminum (Al). In one or more embodiments, the second low refractive layer 30L2 may include silicon-aluminum oxide. For example, the silicon-aluminum oxide may be Si₉Al₂O₁₀, and the silicon-aluminum oxide may be provided as a substitutional solid solution. For example, the silicon-aluminum oxide may be provided as a substitutional solid solution, in which at least a portion of silicon atoms of silicon oxide may be replaced by aluminum atoms. For example, the second low refractive layer 30L2 may include a substitutional solid solution, in which at least a portion of silicon atoms of silicon oxide may be replaced by aluminum atoms.

In one or more embodiments, a refractive index of the second low refractive layer 30L2 may be the same as or similar to a refractive index of the first low refractive layer 30L1. The refractive index of the second low refractive layer 30L2 may be about 1.4 to about 1.6. More specifically, a refractive index of the second low refractive layer 30L2 with respect to a wavelength of 550 nm may be about 1.48. For example, each of the first low refractive layer 30L1 and the second low refractive layer 30L2 may have a refractive index of about 1.4 to about 1.6.

For example, the anti-reflection layer 30AR may have a structure, in which high refractive layers including titanium-niobium oxide provided as a substitutional solid solution and low refractive layers including silicon-aluminum oxide provided as a substitutional solid solution may be alternately stacked. By adjusting a thickness and a refractive index of each of the high refractive layers and the low refractive layers, lights reflected by planes between the respective layers (e.g., a high refractive layer and a low refractive layer) destructively interfere with each other, and thus, the anti-reflection layer 30AR may reduce or decrease the reflectance of externally incident light.

In general, oxide including a plurality of types (kinds) of elements, such as titanium-niobium oxide and/or silicon-aluminum oxide, may be provided as a substitutional solid solution, an interstitial solid solution, and/or a simple mixture. A solid solution may refer to a solid mixture that forms a completely or substantially uniform phase. A substitutional solid solution is a form, in which solute atoms are substituted for the original solvent atoms, so that the solute atoms are placed at the positions of the original solvent atoms. An interstitial solid solution is a form, in which the solute atoms are placed in the spaces between the original solvent atoms. A simple mixture is a form, in which a plurality of types (kinds) of elements each form oxides and such a plurality of types (kinds) of oxides are mixed. For example, the simple mixture may be a mixed form of SiO₂ and Al₂O₃.

The substitutional solid solution may be more stable because bonds are formed between neighboring solute atoms and solvent atoms, and may have improved attaching force because of having a high-density structure. In one or more embodiments, the first high refractive layer 30H1, the first low refractive layer 30L1, the second high refractive layer 30H2, and the second low refractive layer 30L2 may be provided as substitutional solid solutions. Accordingly, stability may be increased because bonds are formed between neighboring solute atoms and solvent atoms, and attaching force may be improved because of having a high-density structure. Thus, even if (e.g., when) the display apparatus 1 is folded, cracks may not occur in the anti-reflection layer 30AR and/or the occurrence of cracks may be reduced.

The high refractive layers including titanium-niobium oxide provided as a substitutional solid solution may be formed on the base layer 30BS at low temperature by utilizing ion-assisted deposition (IAD). In some embodiments, if (e.g., when) IAD is utilized and deposition particles of high-refractive materials are attached to the baser layer 30BS, ionized argons, oxygens, and/or the like may collide together, thereby increasing kinetic energy of the deposition particles. Accordingly, bonding force (e.g., adhesive force and/or attaching force) of a deposited layer may be increased.

In addition, silicon-aluminum oxide provided as a substitutional solid solution may have a high bonding force (e.g., adhesive force and/or attaching force) with other materials. Accordingly, the low refractive layer may improve bonding force (e.g., adhesive force and/or attaching force) between the high refractive layers. For example, the first low refractive layer 30L1 may be between (e.g., arranged between) the first high refractive layer 30H1 and the second high refractive layer 30H2 to improve adhesion between the first high refractive layer 30H1 and the second high refractive layer 30H2, thereby preventing or reducing exfoliation of the second high refractive layer 30H2 from the first high refractive layer 30H1.

The anti-fingerprint layer 30AF may be on (e.g., arranged on) the anti-reflection layer 30AR. More specifically, the anti-fingerprint layer 30AF may be on (e.g., arranged on) the second low refractive layer 30L2. For example, the anti-fingerprint layer 30AF may be on (e.g., arranged on) a surface of the protective layer 30. The anti-fingerprint layer 30AF may reduce abrasion of the surface of the protective layer 30. In one or more embodiments, the anti-fingerprint layer 30AF may include a perfluorinated compound. In one or more embodiments, the anti-fingerprint layer 30AF may include perfluoropolyether (PFPE). In PFPE, highly flexible ether bonds are introduced into a hard and short perfluoroalkyl chain. Accordingly, PFPE may have soft amorphous properties, excellent or suitable anti-fingerprint properties, and excellent or suitable slip properties. However, one or more embodiments are not limited thereto.

The anti-fingerprint layer 30AF may be formed, for example, by a method, such as electron-beam (E-beam) vapor deposition, sputtering, thermal deposition, and/or spin coating. In one or more embodiments, the anti-fingerprint layer 30AF may be formed by E-beam vapor deposition.

As described above, silicon-aluminum oxide provided as a substitutional solid solution has a high bonding force (e.g., adhesive force and/or attaching force) with other materials. Accordingly, if (e.g., when) the anti-fingerprint layer 30AF is directly on (e.g., arranged on) the low refractive layer including silicon-aluminum oxide provided as a substitutional solid solution, bonding force (e.g., adhesive force and/or attaching force) between the low refractive layer and the anti-fingerprint layer 30AF may be high, and thus, the anti-fingerprint layer 30AF may not be easily exfoliated from the anti-reflection layer 30AR.

The light-blocking layer 30LB may be under (e.g., arranged under) the base layer 30BS. More specifically, the light-blocking layer 30LB may be opposite to the anti-reflection layer 30AR with the baser layer 30BS therebetween. In addition, the light-blocking layer 30LB may be positioned along edges of the protective layer 30. For example, the light-blocking layer 30LB may overlap the peripheral area PA of the display panel 10 described above with reference to FIG. 4. Accordingly, the light-blocking layer 30LB may prevent or reduce a wire or circuit in the peripheral area PA of the display panel 10 from being identified from the outside, and may prevent or reduce light leakage of the display panel 10. For example, a region where the light-blocking layer 30LB is may be a bezel area of the display apparatus 1.

The light-blocking layer 30LB may have a single-layer or multi-layer structure, and may include at least one of acrylic urethane, epoxy, polyester, and/or epoxy ester.

In one or more embodiment, the protective layer 30 may further include a hard coating layer between the base layer 30BS and the anti-reflection layer 30AR. The hard coating layer may be directly on (e.g., arranged on) an upper surface of the base layer 30BS to protect the base layer 30BS. The hard coating layer may be formed from a hard coating layer resin including at least one of an organic-based composition, an inorganic-based composition, and/or an organic-inorganic composite composition. For example, a hard coating agent utilized to form the hard coating layer may include at least one of an acrylate-based compound, a siloxane compound, and/or a silsesquioxane compound. In addition, the hard coating agent may further include inorganic particles. Accordingly, the hard coating layer may be an organic layer, an inorganic layer, and/or an organic-inorganic composite layer.

In one or more embodiments, the reflectance of the protective layer 30 may be about 1.5% or less. More specifically, the reflectance of the protective layer 30 may be about 1% or less. The reflectance may be measured in a specular component included (SCI) mode. The measured reflectance of the protective layer 30 was about 0.70%. Accordingly, the protective layer 30 may satisfy desired or required optical properties.

In one or more embodiments, the crack strain of the protective layer 30 may be about 7.0% or greater. More specifically, the crack strain of the protective layer 30 may be about 8.0% or greater. The crack strain may refer to a level of increase in the size of a test sample before cracks occur in the test sample due to stretching, relative to the size of an initial test sample. For example, the protective layer 30 having the structure described above with reference to FIG. 7 was cut to a preset size. A stretching speed was set to 10 millimeters per minute (mm/min), and after performing stretching, the occurrence of cracks was observed with a microscope, and a level of increase in the size of a test sample at the point was measured. The measured crack strain of the protective layer 30 was about 7%. For example, the size of the protective layer 30 having been stretched increased by about 7% compared to the size of the protective layer 30 before being stretched, but no cracks occurred in the stretched protective layer 30. Accordingly, the protective layer 30 may satisfy desired or required mechanical properties (e.g., strength and/or hardness).

In one or more embodiments, a contact angle of a surface of the protective layer 30 with respect to water obtained after applying a load of about 1 kg to the surface of the protective layer 30 by utilizing an eraser and performing reciprocating friction 10,000 times over a distance of 15 mm at a speed of 40 cycles/min may be 95 degrees) (° or greater. For example, abrasion resistance evaluation may be performed by measuring a water contact angle after applying a load of about 1 kg to a surface of the protective layer 30 by utilizing an eraser and reciprocating a distance of 15 mm at a speed of 40 cycles/min 10,000 times.

For example, the protective layer 30 having the structure described above with reference to FIG. 7 was cut into a preset size and fixed to a jig of a scratch tester (Daesung Precision Co., Ltd.), and Rubber stick (Minoan Co., Ltd.) having a diameter of 6 mm was mounted at the tip. The Rubber stick was subjected to reciprocating friction on a surface of the protective layer 30 by setting the moving distance as 15 mm, the moving speed as 40 cycles/min, and the load as 1.0 kg, and then, a water contact angle of the worn surface was measured. The contact angle of the surface of the protective layer 30 with respect to water measured in the abrasion resistance evaluation was 95° or greater.

The surface of the protective layer 30 that is antifouling-treated has hydrophobicity, and if (e.g., when) the surface of the protective layer 30 has hydrophobicity, a contact angle with respect to water may increase. However, the surface of the protective layer 30 may be hydrophilized by external repeated stress and/or strong impact, and if (e.g., when) the surface of the protective layer 30 is hydrophilized, a contact angle with respect to water may be reduced.

If (e.g., when) a contact angle of a surface of the protective layer 30 with respect to water measured in the abrasion resistance evaluation is 95° or greater, it may denote that the surface of the protective layer 30 withstands external stress and impact well. If (e.g., when) a contact angle of a surface of the protective layer 30 with respect to water measured in the abrasion resistance evaluation is less than 95°, it may denote that the surface of the protective layer 30 does not withstand external stress and impact well. Accordingly, if (e.g., when) a contact angle of the surface of the protective layer 30 with respect to water measured after performing 10,000 times of reciprocating friction is 95° or greater, it may indicate that the protective layer 30 satisfies desired or required abrasion resistance (SPEC IN). If (e.g., when) a contact angle of the surface of the protective layer 30 with respect to water measured after performing 10,000 times of reciprocating friction is less than 95°, it may indicate that the protective layer 30 fails to satisfy desired or required abrasion resistance (SPEC OUT). Accordingly, the protective layer 30 may satisfy desired or required abrasion resistance. For example, if the contact angle of the surface of the protective layer 30 with respect to water, measured during the abrasion resistance evaluation, is 95° or greater, it indicates that the surface of the protective layer 30 withstands external stress and impact well. Conversely, if the contact angle is less than 95°, it indicates that the surface does not withstand external stress and impact well. Accordingly, if the contact angle of the surface of the protective layer 30 with respect to water, measured after performing 10,000 cycles of reciprocating friction, is 95° or greater, it indicates that the protective layer 30 satisfies the desired or required abrasion resistance (SPEC IN). If the contact angle is less than 95°, it indicates that the protective layer 30 fails to satisfy the desired or required abrasion resistance (SPEC OUT). Therefore, the protective layer 30 according to one or more embodiments satisfies the desired or required abrasion resistance.

In one or more embodiments, a contact angle of a surface of the protective layer 30 with respect to water obtained after providing a chemical on the surface of the protective layer 30, applying a load of about 1 kg to the surface of the protective layer 30 by utilizing an eraser, and performing reciprocating friction 3,000 times over a distance of 15 mm at a speed of 40 cycles/min may be 95° or greater. For example, chemical resistance evaluation may be performed by measuring a water contact angle after providing a chemical on a surface of the protective layer 30, applying a load of about 1 kg to the surface of the protective layer 30 by utilizing an eraser, and reciprocating a distance of 15 mm at a speed of 40 cycles/min 3,000 times.

For example, the protective layer 30 having the structure described above with reference to FIG. 7 was cut into a preset size and fixed to a jig of a scratch tester (Daesung Precision Co., Ltd.), and Rubber stick (Minoan Co., Ltd.) having a diameter of 6 mm was mounted at the tip. After anhydrous ethanol was sprayed on a surface of the protective layer 30, and then, in the presence of the ethanol, the Rubber stick was subjected to reciprocating friction on the surface of the protective layer 30 by setting the moving distance as 15 mm, the moving speed as 40 cycles/min, and the load as 1.0 kg, the surface of the protective layer 30 was cleaned several times, and a water contact angle of the worn surface was measured. The contact angle of the surface of the protective layer 30 with respect to water measured in the chemical resistance evaluation was 95° or greater.

If (e.g., when) a contact angle with respect to water measured in the chemical resistance evaluation is 95° or greater, it may denote that a surface of the protective layer 30 withstands a chemical well. If (e.g., when) a contact angle with respect to water measured in the chemical resistance evaluation is less than 95°, it may denote that a surface of the protective layer 30 does not withstand a chemical well. Accordingly, if (e.g., when) a contact angle of the surface of the protective layer 30 with respect to water measured after providing a chemical on the surface of the protective layer 30 and performing 3,000 times of reciprocating friction is 95° or greater, it may indicate that the protective layer 30 satisfies desired or required chemical resistance (SPEC IN). If (e.g., when) a contact angle of the surface of the protective layer 30 with respect to water measured after providing a chemical on the surface of the protective layer 30 and performing 3,000 times of reciprocating friction is less than 95°, it may indicate that the protective layer 30 fails to satisfy desired or required chemical resistance (SPEC OUT). Accordingly, the protective layer 30 may satisfy desired or required chemical resistance. For example, if the contact angle with respect to water measured in the chemical resistance evaluation is 95° or greater, it denotes that the surface of the protective layer 30 withstands the chemical well. If the contact angle with respect to water measured in the chemical resistance evaluation is less than 95°, it denotes that the surface of the protective layer 30 does not withstand the chemical well. Accordingly, if the contact angle of the surface of the protective layer 30 with respect to water measured after applying a chemical to the surface and performing 3,000 cycles of reciprocating friction is 95° or greater, it indicates that the protective layer 30 satisfies the desired or required chemical resistance (SPEC IN). If the contact angle is less than 95°, it indicates that the protective layer 30 fails to satisfy the desired or required chemical resistance (SPEC OUT). Therefore, the protective layer 30 according to one or more embodiments satisfies the desired or required chemical resistance.

Although FIG. 7 shows the anti-reflection layer 30AR being in direct contact with the base layer 30BS, one or more embodiments are not limited thereto. For example, a buffer layer 30L3 may be between (e.g., arranged between) the anti-reflection layer 30AR and the base layer 30BS.

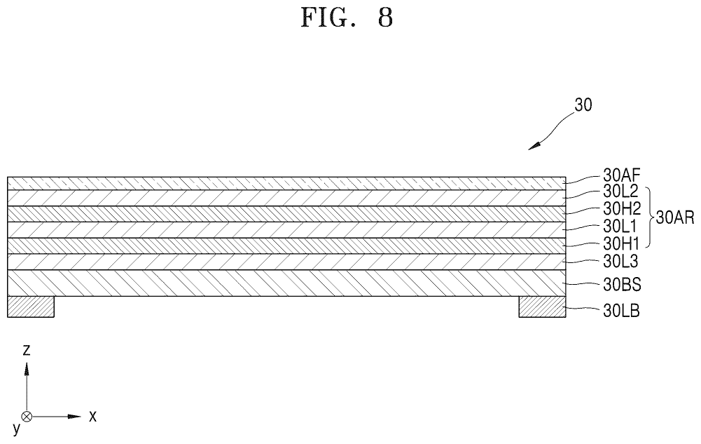

FIG. 8 is a schematic cross-sectional view of the protective layer 30 included in the display apparatus 1 according to one or more embodiments. Because the protective layer 30 included in the display apparatus 1 is similar to the protective layer 30 described above with reference to FIG. 7, differences from the protective layer 30 described above with reference to FIG. 7 are mainly described in more detail.

In one or more embodiments, the protective layer 30 included in the display apparatus 1 according to the one or more embodiments described above with reference to FIG. 7 may include the base layer 30BS, the anti-reflection layer 30AR, the anti-fingerprint layer 30AF, and the light-blocking layer 30 LB. In some embodiments, the protective layer 30 included in the display apparatus 1 according to the present embodiment (e.g., the one or more embodiments described with reference to FIG. 8) may include the base layer 30BS, the anti-reflection layer 30AR, the anti-fingerprint layer 30AF, and the light-blocking layer 30 LB. That is, the protective layer 30 included in the display apparatus 1, as described with reference to FIG. 7, includes the base layer 30BS, the anti-reflection layer 30AR, the anti-fingerprint layer 30AF, and the light-blocking layer 30LB.

However, the protective layer 30 included in the display apparatus 1 according to the present embodiment may further include the buffer layer 30L3 between (e.g., arranged between) the anti-reflection layer 30AR and the base layer 30BS. The buffer layer 30L3 may include a low-refractive material. The buffer layer 30L3 may include a material that is the same as that included in the first low refractive layer 30L1. For example, the buffer layer 30L3 may be composed of the same material as the first low refractive layer 30L1. More specifically, the buffer layer 30L3 may include oxide, and the buffer layer 30L3 may include silicon (Si) and/or aluminum (Al). In one or more embodiments, the buffer layer 30L3 may include silicon-aluminum oxide. For example, the silicon-aluminum oxide may be Si₉Al₂O₁₀, and the silicon-aluminum oxide may be provided as a substitutional solid solution. For example, the silicon-aluminum oxide may be provided as a substitutional solid solution, in which at least a portion of silicon atoms of silicon oxide may be replaced by aluminum atoms. For example, the buffer layer 30L3 may include a substitutional solid solution, in which at least a portion of silicon atoms of silicon oxide may be replaced by aluminum atoms. That is, the protective layer 30 in the display apparatus 1 includes a buffer layer 30L3, made of low-refractive silicon-aluminum oxide, arranged between the anti-reflection layer 30AR and the base layer 30BS, where some silicon atoms are replaced by aluminum atoms.

In one or more embodiments, a refractive index of the buffer layer 30L3 may be the same as or similar to a refractive index of the first low refractive layer 30L1. The refractive index of the buffer layer 30L3 may be about 1.4 to about 1.6. More specifically, a refractive index of the buffer layer 30L3 with respect to a wavelength of 550 nm may be about 1.48. That is, the refractive index of the buffer layer 30L3 is similar to that of the first low refractive layer 30L1, ranging from about 1.4 to about 1.6, and specifically about 1.48 at a wavelength of 550 nm.

In one or more embodiments, the anti-reflection layer 30AR may have a structure, in which high refractive layers including titanium-niobium oxide provided as a substitutional solid solution and low refractive layers including silicon-aluminum oxide provided as a substitutional solid solution are alternately stacked. For example, the first high refractive layer 30H1, the first low refractive layer 30L1, the second high refractive layer 30H2, and the second low refractive layer 30L2 may be provided as substitutional solid solutions. Accordingly, stability may be increased because bonds are formed between neighboring solute atoms and solvent atoms, and attaching force may be improved because of having a high-density structure. Thus, even if (e.g., when) the display apparatus 1 is folded, cracks may not occur in the anti-reflection layer 30AR, and/or the occurrence of cracks may be reduced. That is, the anti-reflection layer 30AR is composed of alternately stacked high refractive layers of titanium-niobium oxide and low refractive layers of silicon-aluminum oxide, both as substitutional solid solutions, enhancing stability and attachment force, thereby reducing or preventing cracks when the display apparatus 1 is folded. In the present context, a substitutional solid solution refers to a type or kind of solid solution where atoms of one element replace atoms of another element within the crystal structure of a solid material. For example, in the high refractive layers of titanium-niobium oxide, some titanium atoms are replaced by niobium atoms. Similarly, in the low refractive layers of silicon-aluminum oxide, some silicon atoms are replaced by aluminum atoms.

As described above, silicon-aluminum oxide provided as a substitutional solid solution may have a high bonding force (e.g., adhesive force and/or attaching force) with other materials. Accordingly, if (e.g., when) a buffer layer including silicon-aluminum oxide provided as a substitutional solid solution is between (e.g., arranged between) the anti-reflection layer 30AR and the base layer 30BS, bonding force (e.g., adhesive force and/or attaching force) between the buffer layer and the base layer 30BS may be high, and thus, the anti-reflection layer 30AR may not be easily exfoliated from the base layer 30BS. That is, silicon-aluminum oxide as a substitutional solid solution has a high bonding force with other materials, so when used as a buffer layer between the anti-reflection layer 30AR and the base layer 30BS, it ensures strong adhesion, preventing or protecting the anti-reflection layer from easily exfoliating.

In one or more embodiments, a protective layer, in which the occurrence of cracks may be reduced during folding of a display apparatus, and a display apparatus including the protective layer may be implemented. However, one or more embodiments are not limited by such an effect.

As utilized herein, the terms “substantially,” “about,” and similar terms are utilized as terms of approximation and not as terms of degree, and are intended to account for the inherent deviations in measured or calculated values that would be recognized by those of ordinary skill in the art. “About” or “approximately,” as utilized herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the context of the present disclosure and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A device of preparing a protective layer, a device of preparing a display apparatus including the protective layer, and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A protective layer comprising:
a base layer;
a first high refractive layer on the base layer and comprising titanium and niobium;
a first low refractive layer on the first high refractive layer and comprising silicon and aluminum;
a second high refractive layer on the first low refractive layer and comprising a material that is the same as that in the first high refractive layer;
a second low refractive layer on the second high refractive layer and comprising a material that is the same as that in the first low refractive layer; and
an anti-fingerprint layer on the second low refractive layer and comprising a perfluorinated compound.

2. The protective layer of claim 1, wherein the first high refractive layer comprises titanium-niobium oxide.

3. The protective layer of claim 1, wherein the first low refractive layer comprises silicon-aluminum oxide.

4. The protective layer of claim 1, wherein each of the first high refractive layer and the second high refractive layer has a refractive index of about 1.7 to about 3.0.

5. The protective layer of claim 1, wherein each of the first low refractive layer and the second low refractive layer has a refractive index of about 1.3 to about 1.6.

6. The protective layer of claim 1, wherein the first high refractive layer comprises a substitutional solid solution, in which at least a portion of titanium atoms of titanium oxide is replaced by niobium atoms.

7. The protective layer of claim 1, wherein the first low refractive layer comprises a substitutional solid solution, in which at least a portion of silicon atoms of silicon oxide is replaced by aluminum atoms.

8. The protective layer of claim 1, wherein the first high refractive layer comprises Ti₁₄Nb₃O₃₅, and the first low refractive layer comprises Si₉Al₂O₁₀.

9. The protective layer of claim 1, further comprising a buffer layer between the base layer and the first high refractive layer.

10. The protective layer of claim 9, wherein the buffer layer comprises a material that is the same as that in the first low refractive layer.

11. A display apparatus comprising:
a display panel;
a cover window on the display panel; and
a protective layer on the cover window,
wherein the protective layer comprises:
a base layer;
a first high refractive layer on the base layer and comprising titanium and niobium;
a first low refractive layer on the first high refractive layer and comprising silicon and aluminum;
a second high refractive layer on the first low refractive layer and comprising a material that is the same as that in the first high refractive layer;
a second low refractive layer on the second high refractive layer and comprising a material that is the same as that in the first low refractive layer; and
an anti-fingerprint layer on the second low refractive layer and comprising a perfluorinated compound.

12. The display apparatus of claim 11, wherein the first high refractive layer comprises titanium-niobium oxide.

13. The display apparatus of claim 11, wherein the first low refractive layer comprises silicon-aluminum oxide.

14. The display apparatus of claim 11, wherein each of the first high refractive layer and the second high refractive layer has a refractive index of about 1.7 about to 3.0.

15. The display apparatus of claim 11, wherein each of the first low refractive layer and the second low refractive layer has a refractive index of about 1.3 to about 1.6.

16. The display apparatus of claim 11, wherein the first high refractive layer comprises a substitutional solid solution, in which at least a portion of titanium atoms of titanium oxide is replaced by niobium atoms.

17. The display apparatus of claim 11, wherein the first low refractive layer comprises a substitutional solid solution, in which at least a portion of silicon atoms of silicon oxide is replaced by aluminum atoms.

18. The display apparatus of claim 11, wherein the first high refractive layer comprises Ti₁₄Nb₃O₃₅, and the first low refractive layer comprises Si₉Al₂O₁₀.

19. The display apparatus of claim 11, further comprising a buffer layer between the base layer and the first high refractive layer, wherein the buffer layer comprises a material that is the same as that in the first low refractive layer.

20. A electronic apparatus including the display apparatus of claim 11.
